(19) United States
(12) Patent Application Publication
(10) Pub. No.: US 2003/0071288 A1
(43) Pub. Date: Apr. 17, 2003

(54) Two-bit split-gate non-volatile memory transistor

(75) Inventor: Ishai Nachumovsky, Zichron Yaakov (IL)

Correspondence Address: BEVER HOFFMAN & HARMS, LLP, 2099 GATEWAY PLACE, SUITE 320, SAN JOSE, CA, 951101017

(73) Assignee: Tower Semiconductor Ltd.

(21) Appl. No.: 09/975,049

(22) Filed: Oct. 10, 2001

(51) Int. Cl. H01L 27/148

(52) U.S. Cl. 257/225

(57) ABSTRACT

A 2-bit non-volatile memory (NVM) transistor having a pair of isolated floating gate electrodes is provided. One of the floating gate electrodes is located over a first source/drain region, and a first adjacent end of a channel region. The other floating gate electrode is located over a second source/drain region and a second adjacent end of the channel region. A control gate extends over both floating gate electrodes and a centrally located portion of the channel region. The floating gate electrodes are independently programmed and independently read, thereby enabling the NVM transistor to effectively store 2-bits of data.

### FIELD OF THE INVENTION

The present invention relates to non-volatile memory (NVM) transistors. More specifically, the present invention relates to a 2-bit split-gate non-volatile memory transistor.

### RELATED ART

FIG. 1 is a cross sectional view of a conventional 2-bit non-volatile semiconductor memory transistor 10 that utilizes asymmetrical charge trapping. 2-bit NVM transistor 10, which is fabricated in p-type substrate 12, includes n+ source region 14, n+ drain region 16, channel region 17, silicon oxide layer 18, silicon nitride layer 20, silicon oxide layer 22, and control gate 24. Oxide layer 18, nitride layer 20 and oxide layer 22 are collectively referred to as ONO layer 21. NVM transistor 10 operates as follows. A first programming operation is performed by connecting source region 14 to ground, connecting drain region 16 to a programming voltage of about 5-8 Volts, and connecting control gate 24 to a voltage of about 10 Volts. As a result, electrons are accelerated from source region 14 to drain region 16. Near drain region 16, some electrons gain sufficient energy to pass through oxide layer 18 and be trapped in nitride layer 20 in accordance with a phenomenon known as hot electron injection. Because nitride layer 20 is non-conductive, the injected charge remains localized within charge trapping region 26 in nitride layer 20. The charge stored by localized charge trapping region 26 represents a first bit of data stored by NVM transistor 10.

The first bit of NVM transistor 10 is read by applying 0 Volts to the drain region 16, 2 Volts to the source region 14, and 3 volts to the gate electrode. If charge is stored in charge trapping region 26 (i.e., the first bit of NVM transistor 10 is programmed), then NVM transistor 10 does not conduct current under these conditions. If there is no charge stored in charge trapping region 26 (i.e., the first bit of NVM transistor 10 is erased), then NVM transistor 10 conducts current under these conditions. The current, or lack of current, is sensed by a sense amplifier to determine the state of the first bit of NVM transistor 10.

Note that the polarity of the voltage applied across source region 14 and drain region 16 is reversed during the program and read operations. That is, the first bit of NVM transistor 10 is programmed in one direction (with source region 14 grounded), and read the opposite direction (with drain region 16 grounded). As a result, the read operation is referred to as a reverse read operation. NVM transistor 10 is described in more detail in U.S. Pat. No. 5,768,192.

NVM transistor 10 also includes a second charge-trapping region in nitride layer 20, which is located adjacent to source region 14. FIG. 2 illustrates both the first charge trapping region 26 (described above in connection with FIG. 1), and the second charge-trapping region 28 in dashed lines. The second charge trapping region 28 is used to store a charge representative of a second bit. The second charge trapping region 28 is programmed and read in a manner similar to the first charge-trapping region 26. More specifically, the second charge trapping region 28 is programmed and read by exchanging the source and drain voltages described above for programming and reading the first charge trapping region 26. Thus, the second charge trapping region 28 is programmed by applying 0 Volts to drain region 16, applying 5-8 Volts to source region 14 and applying 10 Volts to control gate 24. Similarly, the second charge-trapping region 28 is read by applying 0 Volts to source region 14, 2 Volts to drain region 16, and 3 Volts to control gate 24.

Note that because nitride layer 20 is non-conductive, the charges stored in the first and second charge trapping regions 26 and 28 remain localized within nitride layer 20. Also note that the state of the first charge-trapping region 26 does not interfere with the reading of the charge stored in the second charge-trapping region 28 (and vice versa). Thus, if the first charge trapping region 26 is programmed (i.e., stores charge) and the second charge trapping region 28 is not programmed (i.e., does not store charge), then a reverse read of the first charge trapping region will not result in significant current flow. However, a reverse read of the second bit will result in significant current flow because the high voltage applied to drain region 16 will result in unperturbed electronic transfer in the pinch off region adjacent to first charge trapping region 26. Thus, the information stored in the first and second charge trapping regions 26 and 28 is read properly.

Similarly, if both the first and second charge-trapping regions are programmed, a read operation in either direction will result in no significant current flow. Finally, if neither the first charge trapping region 26 nor the second charge trapping region 28 is programmed, then read operations in both directions will result in significant current flow.

NVM transistor 10 has the following disadvantages. First, electrons and holes within the charge trapping regions 26 and 28 can migrate over time, thereby resulting in cycling/endurance degradation. Moreover, NVM transistor 10 is subject to over-programming and over-erase conditions. Furthermore, the nitride charge storage layer 20 structure cannot be erased by exposure to UV light, such that the threshold voltage of the NVM transistor cannot be reduced after manufacture. Finally, a relatively high current is required to program NVM transistor 10.

It would therefore be desirable to have a 2-bit non-volatile memory transistor that overcomes the above-described deficiencies of NVM transistor 10.

### SUMMARY

Accordingly, the present invention provides a 2-bit split gate non-volatile memory (NVM) transistor, which is fabricated in a semiconductor region having a first conductivity type. First and second source/drain regions having a second conductivity type, opposite the first conductivity type, are located in the semiconductor region. In one embodiment, the first and second source/drain regions extend into diffusion bit lines. A channel region separates the first and second source drain regions in the semiconductor region. A gate dielectric layer is located over the channel region and portions of the first and second source/drain regions. In one embodiment, the gate dielectric layer is silicon oxide.

A first floating gate electrode is located on the gate dielectric layer over portions of the channel region and the first source/drain region. The first floating gate electrode stores charge representative of a first data bit. A second floating gate electrode is located on the gate dielectric layer over portions of the channel region and the second source/drain region. The second floating gate electrode stores charge representative of a second data bit.

The first and second floating gate electrodes are separated by a gap over the channel region. In one embodiment, the first and second floating gate electrodes are polysilicon.

A dielectric layer is located over most of the first floating gate electrode and most of the second floating gate electrode. The dielectric layer also extends into the gap between the first and second floating gate electrodes, where the dielectric layer contacts the underlying gate dielectric layer. In one embodiment, the dielectric layer includes a silicon oxide layer and a silicon nitride layer formed over the silicon oxide layer. Oxide is thermally grown on exposed outer edges of the first and second floating gate electrodes, which are not covered by the dielectric layer. At this time, oxide is also thermally grown over exposed portions of the diffusion bit lines and the dielectric layer.

A control gate is located over the dielectric layer. The control gate therefore extends over the first and second floating gate electrodes and the channel region. In one embodiment, the control gate is polycide or salicide.

Advantageously, the process required to fabricate the NVM transistor of the present invention is relatively simple. Moreover, because the charge storage regions are formed by first and second floating gate electrodes that are isolated from each other, charge migration does not exist. Furthermore, the NVM transistor of the present invention is not subject to over-programming or over-erase conditions. In addition, the polysilicon structure allows the first and second floating gate electrodes to be erased by exposure to UV light, thereby reducing the threshold voltage of the NVM transistor after manufacture. Moreover, a relatively low current is required to program the NVM transistor of the present invention.

The present invention also includes a method for operating the 2-bit non-volatile memory transistor, which includes the steps of (1) programming the first floating gate by hot electron injection using a first set of programming voltages, wherein the second floating gate is in an erased state when the first floating gate is programmed, and (2) programming the second floating gate by hot electron injection using a second set of programming voltages, wherein the first floating gate is in a programmed state when the second floating gate is programmed. The voltage applied to the control gate in the second set of programming voltages is greater than the voltage applied to the control gate in the first set of programming voltages. In a particular embodiment, the voltage applied to the control gate in the first set of programming voltages is about 1-2 Volts, and the voltage applied to the control gate in the second set of programming voltages is about 3-4 Volts.

This method can further include the steps of (a) reading the state of the first floating gate by applying a first set of read voltages to the transistor, and (b) reading the state of the second floating gate by applying a second set of read voltages to the transistor, wherein the first floating gate is subjected to a reverse read operation in a first direction, and the second floating gate is subjected to a reverse read operation in a second direction, opposite the first direction.

The present invention also includes a method for fabricating the NVM transistor. In one embodiment, this method includes the steps of (1) forming a gate dielectric layer over a semiconductor substrate having a first conductivity type, (2) forming floating gate layer over the gate dielectric layer, (3) removing a first portion of the floating gate layer, thereby creating an opening through the floating gate layer, (4) depositing a dielectric layer over the floating gate layer, wherein a portion of the dielectric layer extends into the opening and onto the gate dielectric layer, (5) removing a second portion of the floating gate layer, thereby creating first floating gate and a second floating gate, wherein a first opening is located adjacent to the first floating gate, and a second opening is located adjacent to the second floating gate, (6) implanting impurities having a second conductivity type, opposite the first conductivity type, into the substrate, through the first and second openings, (7) thermally growing oxide on the substrate and sidewalls of the first and second gate electrodes through the first and second openings, and (8) depositing a control gate over the dielectric layer and the oxide.

The present invention will be more fully understood in view of the following description and drawings.

### BRIEF DESCRIPTION OF THE DRAWINGS

FIGS. 1 and 2 are cross sectional views of a conventional 2-bit non-volatile semiconductor memory transistor that utilizes asymmetrical charge trapping.

FIG. 3 is a schematic diagram of a 2×2 array of 2-bit non-volatile memory (NVM) transistors in accordance with one embodiment of the present invention.

FIGS. 4-12 are cross sectional views that illustrate the fabrication of the NVM transistors of FIG. 3 in accordance with one embodiment of the present invention.

FIG. 13 is a circuit diagram illustrating an erase operation of the array of FIG. 3 in accordance with one embodiment of the present invention.

FIGS. 14A and 14B illustrate read operations of the floating gates of an NVM transistor of the array of FIG. 3 in accordance with one embodiment of the present invention.

FIGS. 15A and 15B illustrate programming operations of the floating gates of an NVM transistor of the array of FIG. 3 in accordance with one embodiment of the present invention.

### DETAILED DESCRIPTION

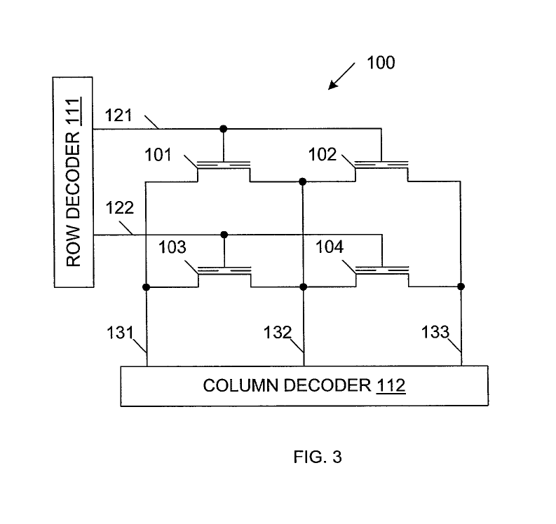

FIG. 3 is a schematic diagram of a 2×2 array 100 of 2-bit non-volatile memory (NVM) transistors 101-104 in accordance with one embodiment of the present invention. While a 2×2 array is shown, it is understood that arrays having other sizes can be implemented, and are considered to fall within the scope of the invention. Array 100 also includes row decoder 111, column decoder 112, word lines 121-122 and bit lines 131-133. Word line 121 is coupled to the control gates of NVM transistors 101-102, and word line 122 is coupled to the control gates of NVM transistors 103-104. As described in more detail below, word lines 121-122 are polycide or salicide in the described embodiment. Word lines 121-122 are also coupled to row decoder 111. Bit lines 131-133 are coupled to the source/drain regions of NVM transistors 101-104, as illustrated. As described in more detail below, bit lines 131-133 are formed by doped diffusion regions in a semiconductor substrate. These doped diffusion regions can be coupled to other doped diffusion regions by metal strap lines. Bit lines 131-133 are also coupled to column decoder 112.

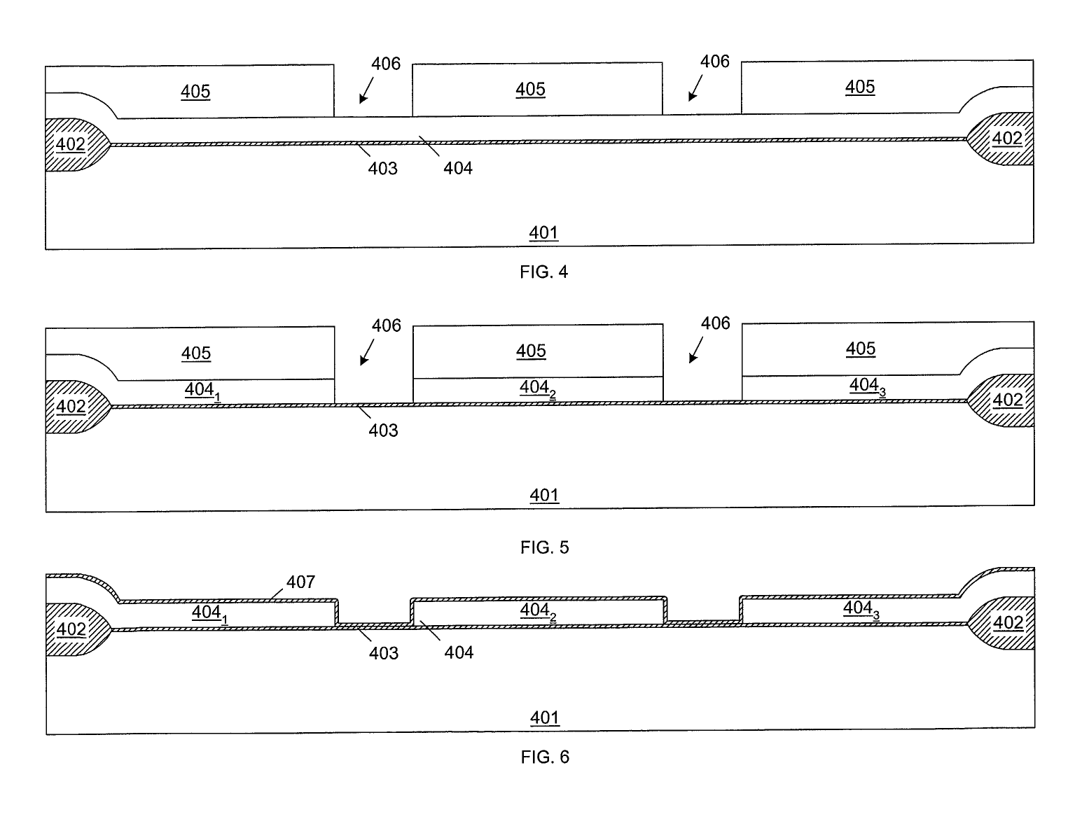

FIGS. 4-12 are cross sectional views that illustrate the fabrication of NVM transistors 101 and 102 in accordance with one embodiment of the present invention. NVM transistors 103 and 104 (not shown in FIGS. 4-12) are fabricated at the same time as NVM transistors 101 and 102.

As illustrated in FIG. 4, array 100 is fabricated in a semiconductor region 401. In the described embodiment, semiconductor region 401 is a p-type well formed in a monocrystalline silicon substrate. Semiconductor region 401 has a dopant concentration of about 5e16-2e17 atoms/cm . In other embodiments, semiconductor region 401 can be a p-type silicon substrate. Field oxide 402 is thermally grown at the upper surface of substrate 401 using a conventional local oxidation of silicon (LOCOS) process. In the described embodiment, field oxide 402 is grown to a thickness in the range of about 4000 to 8000 Å. In the described embodiment, the field oxide is grown to a thickness of about 6000 Å. In an alternate embodiment, field oxide 402 can be replaced with a shallow trench isolation (STI) structure.

After field oxide 402 has been grown, a sacrificial oxide layer (not shown) is grown and then removed (etched) with a diluted hydrofluoric acid (HF). In one embodiment, a blanket threshold voltage implant is performed through the sacrificial oxide. However, in the described embodiment, no threshold voltage implant is performed through the sacrificial oxide. Rather, the required threshold voltage implant is performed as described in more detail below.

Field oxide 402 defines the perimeter of the area where the NVM transistors 101-104 of array 100 are fabricated. However, field oxide 402 is not used to provide isolation between NVM transistors 101-104. For this reason, the resulting configuration of NVM transistors is referred to as a fieldless array of NVM transistors.

Gate dielectric layer 403 is then thermally grown or deposited on the upper surface of semiconductor region 401. In the described embodiment, gate dielectric layer 403 is silicon oxide, which is thermally grown to a thickness in the range of about 50 to 150 Å over the upper surface of semiconductor region 401. In a particular embodiment, gate dielectric layer 403 has a thickness of about 70 Å.

Polysilicon layer 404 is then deposited over field oxide 402 and gate oxide layer 403. As described in more detail below, polysilicon layer 404 is used to create the charge storage regions of NVM transistors 101-104. In the described embodiment, polysilicon layer 404 is undoped polysilicon deposited to a thickness in the range of 1000 to 3000 Å. In a particular embodiment, polysilicon layer 404 has a thickness of about 2000 Å. In an alternate embodiment, polysilicon layer 404 can be doped.

A photoresist mask 405, having openings 406, is formed over polysilicon layer 404. As will become apparent in view of the following disclosure, openings 406 define certain edges of the floating gate electrodes of the NVM transistors. Each of openings 406 has a width that corresponds with the minimum line width of the process used to fabricate the array. In the described embodiment, the process has a minimum line width of 0.18 microns, such that each of openings 406 has a width of 0.18 microns.

As illustrated in FIG. 5, polysilicon layer 404 is etched through openings 406, thereby creating polysilicon regions 404₁, 404₂ and 404₃. This etch is controlled to leave underlying gate oxide layer 403 substantially intact.

As illustrated in FIG. 6, photoresist layer 405 is stripped, and a thin dielectric layer 407 is deposited over the resulting structure. In the described embodiment, dielectric layer 407 includes a silicon oxide layer and a silicon nitride layer, which is deposited over the silicon oxide layer. In one embodiment, the silicon oxide layer has a thickness in the range of about 50 to 200 Å, and the silicon nitride layer has a thickness in the range of about 50 to 200 Å. In a particular embodiment, both the silicon oxide layer and the silicon nitride layer have a thickness of about 70 Å, such that dielectric layer 407 has a thickness of about 140 Å. In an alternate embodiment, the silicon nitride layer can be replaced with a silicon oxynitride (SiON) layer. In the described embodiment, the upper surface of dielectric layer 407 cannot be silicon oxide, for reasons that will become apparent in view of the following disclosure.

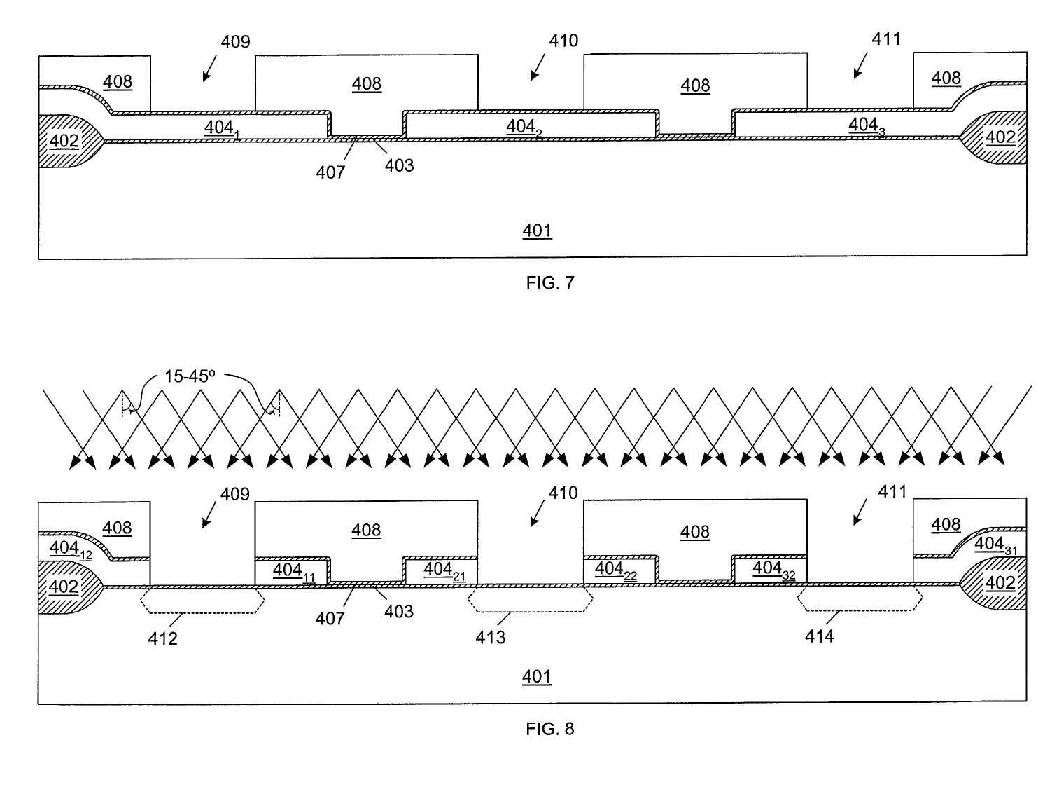

As illustrated in FIG. 7, a photoresist mask 408, having openings 409-411, is formed over dielectric layer 407. As will become apparent in view of the following disclosure, openings 409-411 define certain edges of the floating gates of the NVM transistors. Each of openings 409-411 has a width that corresponds with the minimum line width of the process being used to fabricate the array. In the described embodiment, each of openings 409-411 has a width of 0.18 microns. Openings 409-411 are offset with respect to openings 406 (FIGS. 4-5). In the described embodiment, openings 409-411 are offset by 0.18 microns with respect to openings 406.

As illustrated in FIG. 8, a first etch is performed through openings 409-411, thereby removing the exposed portions of dielectric layer 407. A second etch is then performed through openings 409-411, thereby removing the exposed portions of polysilicon regions 4041-4043. This second etch is controlled to leave the underlying portions of gate dielectric layer 403 substantially intact. The remaining portions of polysilicon regions 404₁-404₃ are labeled as polysilicon regions 404₁₁, 404₂₁, 404₂₁, 404₂₂, 404₃₁, and 404₃₂. As described in more detail below, polysilicon regions 404₁₁ and 404₂₁ form the floating gate electrodes of NVM transistor 101, and polysilicon regions 404₂₂ and 404₃₂ form the floating gate electrodes of NVM transistor 102.

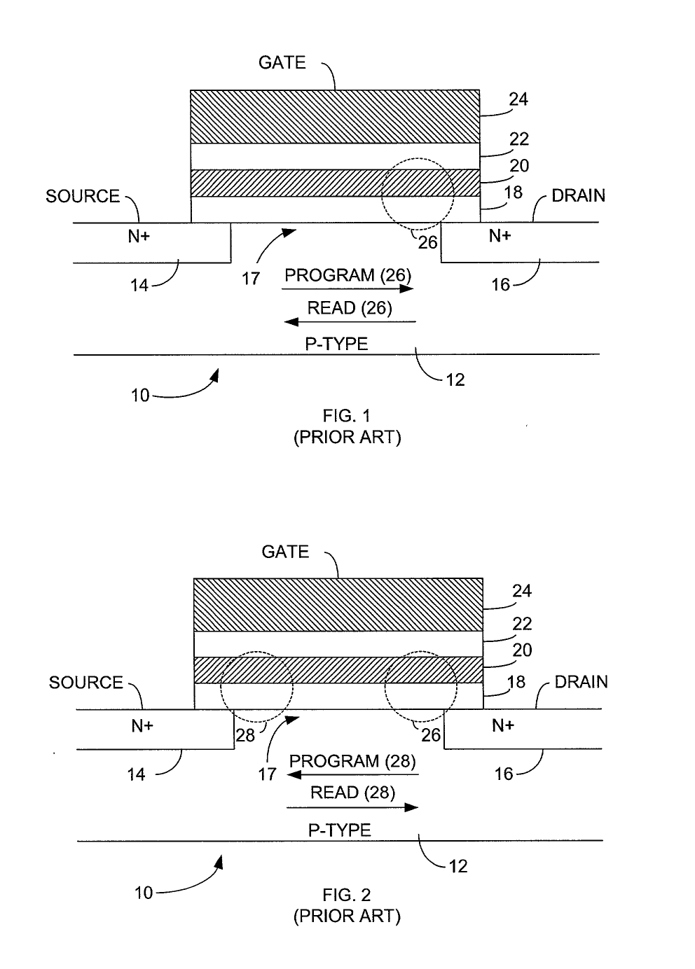

Openings 409-411 also define the diffusion bit lines of array 100. More specifically, openings 409, 410 and 411 define the locations of diffusion bit lines 131, 132 and 133, respectively. After the above-described etching steps are completed, high angle implants are performed through openings 409-411. More specifically, a P-type impurity, such as boron, is implanted through openings 409-411 411 at high angles with respect to the upper surface of semiconductor substrate 401, such that the dopant extends under the edges of photoresist mask 408. In accordance with one embodiment of the present invention, the high angle implants are performed by implanting P-type impurities with a dopant density in the range of 1e13 to 5e13 ions/cm², and an implantation energy in the range of 40 to 100 KeV. In a particular embodiment, the high angle implants are performed with a dopant density of about 2.2e13 ions/cm² and an implantation energy of about 25 KeV. In one embodiment, the high angle implants are performed at angles in the range of 15 to 45 degrees from the vertical axis of FIG. 8, which extends perpendicular to the upper surface of substrate 401. In the described embodiment, the high angle implants are performed at angles approximately 25 degrees from the vertical axis of FIG. 8. The implanted boron serves to adjust the threshold voltages of NVM transistors 101-104. The implanted p-type impurities are illustrated as regions 412-414 in FIG. 8. In an alternate embodiment, the p-type impurities can be implanted along the vertical axis of FIG. 8. Note that in the described example, the pocket implant (and other process features) are less critical than in the NVM transistor 10 of FIGS. 1 and 2, because a simpler process technology is being used in the present invention.

In an alternative embodiment, an additional counter-doping implant can be implemented. The counter doping implant is performed by implanting an n-type impurity, such as phosphor, using parameters similar to the parameters of the above-described high angle implants. The n-type impurity provides improved junction edge optimization. In yet another embodiment, counter-doping is achieved by performing a blanket low energy implant of an n-type impurity over the entire array, after the formation of field oxide 402.

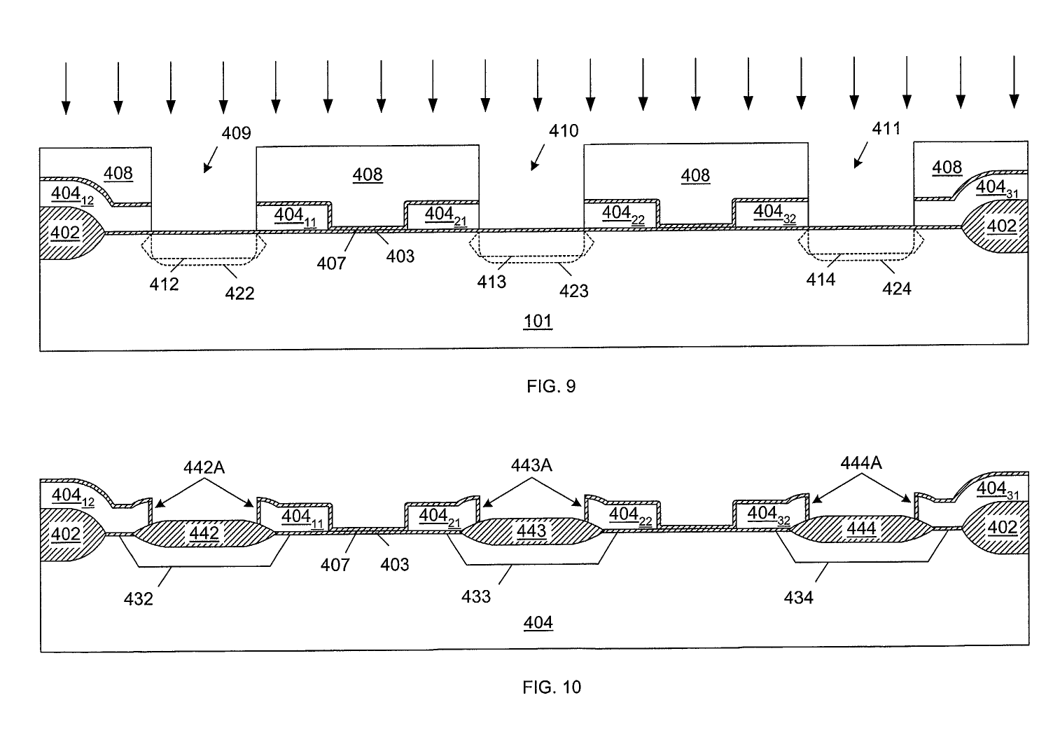

After performing the high angle implants, an N-type impurity, such as arsenic, is implanted through openings 409-411 of photoresist mask 408. In one embodiment, arsenic is implanted with a dopant density in the range of 1e15 to 1e16 ions/cm² and an implantation energy in the range of 30 to 100 KeV. In a particular embodiment, arsenic is implanted with a dopant density of about 3e15 ions/cm² and an implantation energy of about 60 KeV. The implanted N-type impurities are illustrated as regions 422-424 in FIG. 9.

Photoresist mask 408 is then stripped, and a thermal oxidation step is performed, thereby creating bit line oxide regions 442-444 and sidewall oxide regions 442A-444A, as illustrated in FIG. 10. This thermal oxidation step also results in the formation of a thin silicon oxide layer over the exposed silicon nitride of dielectric layer 407. The growth of bit line oxide regions 442-444 causes the portions of polysilicon regions 404₁₁-404₁₁, 404₂₁-404₂₂ and 404₃₁-404₃₂, which are adjacent to bit line oxide regions 442-444 to bend upward. In one embodiment, the bit line oxide is thermally grown using a wet oxidation process at a temperature in the range of 800 to 1000° C. to a thickness in the range of 100 to 500 Å. In a particular embodiment, the bit line oxide is thermally grown using a wet oxidation process at a temperature of about 900° C. to a thickness of about 200 Å. This oxidation step also activates and diffuses the implanted impurities 412-414 and 422-424, thereby forming diffusion bit lines 432-434. Note that diffusion bit lines 432-434 diffuse under polysilicon regions 404₁₁-404₁₁, 404₂₁-404₂₂ and 404₃₁-404₃₂, as illustrated. (Subsequent high temperature processing steps complete the activation of the implanted impurities in regions 412-414 and 422-424). Normally, the relatively low temperature of 700° C. would result in very slow oxidation of silicon. However, the heavy doping of diffusion bit lines 432-434 increases the rate of silicon oxidation by approximately a factor of four. Consequently, low temperature oxidation at 700° C., which provides better control, can be used.

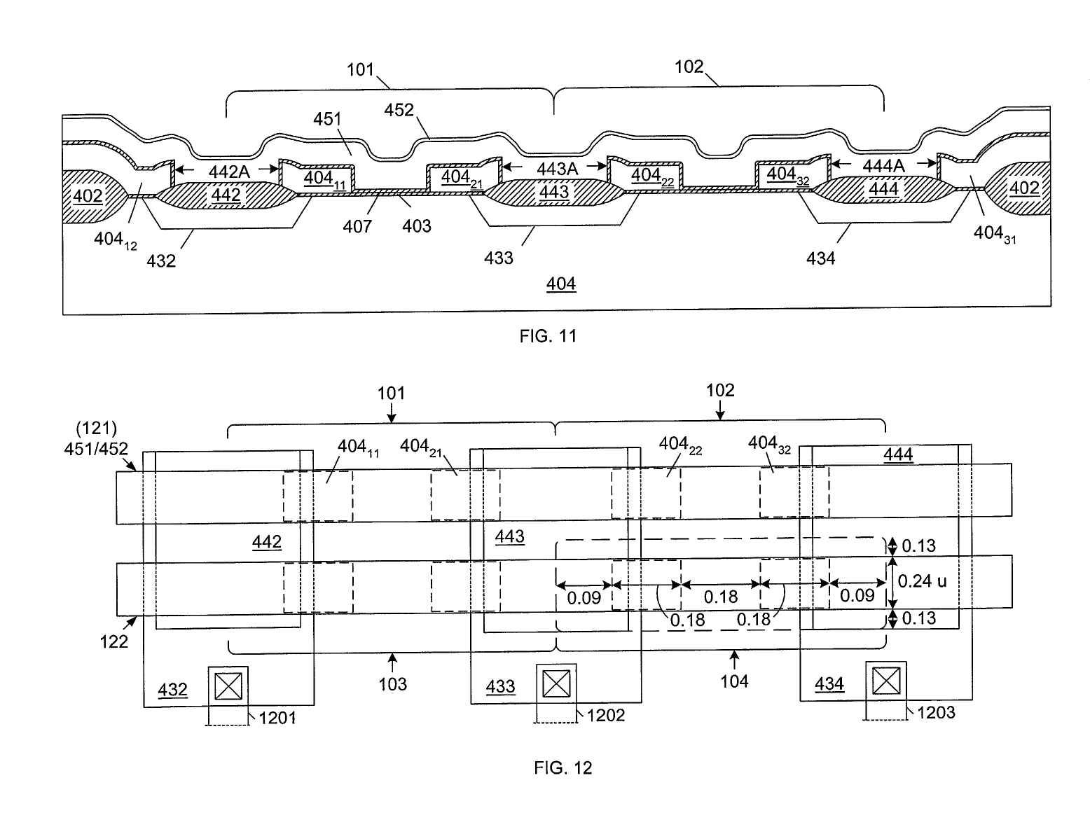

As illustrated in FIG. 11, a blanket layer of polysilicon 451 is then deposited over the upper surface of the resulting structure. In some embodiments, phosphorus oxychloride (POCl₃) is used to dope polysilicon layer 451 to increase the conductivity of polysilicon layer 451. Other embodiments may implant impurities such as phosphorus ions to increase the conductivity of polysilicon layer 451. A layer of metal silicide, such as tungsten silicide, is deposited directly on polysilicon layer 451 to form metal silicide layer 452. In an alternate embodiment, a blanket layer of a refractory metal, such as tungsten, titanium, or cobalt, is sputtered over the upper surface of polysilicon layer 451, and subsequently reacted to form a metal silicide.

A photoresist mask (not shown) is then formed over the resulting structure. This photoresist mask is patterned to define the control gates and word lines of the NVM transistors 101-104. An etch is then performed to remove the portions of metal silicide layer 452 and polysilicon layer 451 that are exposed by the photoresist mask. In one embodiment, this polycide etch is a dry etch. Tungsten silicide layer 452 is etched with a gas mixture of HBr, SF₆ and He. Polysilicon layer 451 is etched with a gas mixture of HBr and Cl₂.

After the polycide etch is completed, the photoresist mask is stripped and a tungsten silicide anneal is then performed at 900° C. with low oxygen flow. (This anneal adheres the tungsten silicide to the underlying polysilicon and is part of the activation of the impurities in the buried diffusion bit lines 432-434). A boron implant is then performed to prevent current leakage between diffusion bit lines at the locations between adjacent gates electrodes in the fieldless array. This boron implant is a blanket implant, with no mask protection provided on the wafer. In one embodiment, boron is implanted at a dopant density in the range of 1e12 to 6e12 ions/cm² and an energy in the range of 20 to 60 KeV. In a particular embodiment, boron is implanted at a dopant density of about 3e12 ions/cm² and an energy of about 30 KeV.

FIG. 12 is a top view of NVM transistors 101-104. NVM transistors 101-102 are labeled with the reference numbers described above in FIGS. 4-11. Each of NVM transistors 101-104 has a horizontal dimension of 0.72 microns (between the centers of the adjacent diffusion bit lines), and a vertical dimension of 0.5 microns. These dimensions are shown on NVM transistor 104 in FIG. 12. The area of each NVM transistor is therefore 0.36 u², with a per bit area of 0.18 u².

The operation of NVM transistors 101-104 in accordance with one embodiment of the present invention will now be described.

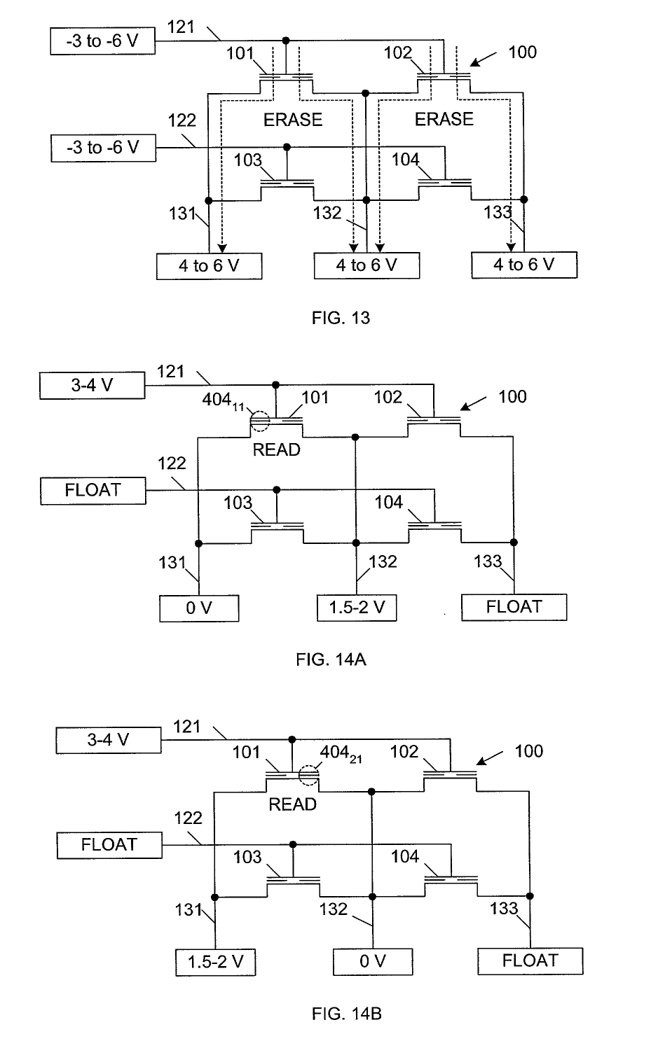

FIG. 13 is a circuit diagram illustrating an erase operation of array 100. In the described embodiment, array 100 is operated as a flash memory, such that all of the NVM transistors 101-104 in the array are erased as a block. To accomplish this, column decoder 112 is controlled to apply an erase voltage of 4 to 6 Volts to bit lines 131-133, and row decoder 111 is controlled to apply an erase voltage of −3 to −6 Volts to word lines 121-122. Under these conditions, electrons are drawn out of the floating gate electrodes (e.g., floating gate electrodes 404₁₁, 404₂₁, 404₂₂ and 404₃₂) of NVM transistors 101-104, thereby leaving these floating gate electrodes substantially uncharged. Note it is not possible to over-erase NVM transistors 101-104 because of the portion of the channel region located between the floating gates of each transistor. For example, even if floating gates 404₁₁, and 404₂₁ are over-erased (and thereby exhibit a positive charge), the portion of the channel region located between these floating gates will not be significantly affected by the positive charge on these floating gates. Thus, NVM transistor 101 will turn on in response to the over-erased floating gates 404₁₁, and 404₂₁. Although FIG. 13 illustrates all of the NVM transistors 101-104 being erased at the same time, in other embodiments, these NVM transistors can be erased in sections.

FIGS. 14A and 14B illustrate read operations of floating gates 404₁₁ and 404₂₁, respectively, of NVM transistor 101. As illustrated in 14A, floating gate 404₁₁ is read as follows. Row decoder 111 is controlled to apply a voltage of about 3-4 Volts to the control gate of NVM transistor 101 via word line 121. Column decoder 112 is controlled to apply a voltage of 0 Volts to bit line 131 and a voltage of about 1.5 to 2 Volts to bit line 132. Under these conditions, relatively large read current will flow through NVM transistor 101 if floating gate 40411 is not programmed. Conversely, a relatively small current will flow through NVM transistor 101 if floating gate 404₁₁ is programmed. Column decoder 112 further couples a sense amplifier (not shown) to bit lines 131-132 in order to sense the read current. In response, the sense amplifier provides an amplified signal representative of the current flow through NVM transistor 101. As will become apparent in view of the following described programming operations, floating gate 404₁₁ is read using a reverse read operation.

As illustrated in 14B, the state of floating gate 404₂₁ is read as follows. Row decoder 111 is again controlled to apply a voltage of about 3-4 Volts to the control gate of NVM transistor 101 via word line 121. Column decoder 112 is controlled to apply a voltage of 0 Volts to bit line 132 and a voltage of about 1.5 to 2 Volts to bit line 131. Under these conditions, a relatively large read current will flow through NVM transistor 101 if floating gate 404₂₁ is not programmed. Conversely, a relatively small read current will flow through NVM transistor 101 if floating gate 404₂₁ is programmed. Column decoder 112 further couples a sense amplifier (not shown) to bit lines 131-132 in order to sense the read current. In response, the sense amplifier provides an amplified signal representative of the current flow through NVM transistor 101. As will become apparent in view of the following described programming operations, floating gate 404₂₁ is read using a reverse read operation.

Table 1 below summarizes the read currents for the possible read operations of NVM transistor 101.

TABLE 1

| | | | | | State of | State of | |
|---|---|---|---|---|---|---|---|
| | | | | | Floating | Floating | Read |
| WL 121 | BL 131 | | BL 132 | | Gate 404₁₁ | Gate 404₂₁ | Current |
| 3-4 V | 0 | V | 1.5-2 | V | Programmed | Programmed | Low |
| 3-4 V | 0 | V | 1.5-2 | V | Programmed | Erased | Low |
| 3-4 V | 0 | V | 1.5-2 | V | Erased | Programmed | High |
| 3-4 V | 0 | V | 1.5-2 | V | Erased | Erased | High |
| 3-4 V | 1.5-2 | V | 0 | V | Programmed | Programmed | Low |
| 3-4 V | 1.5-2 | V | 0 | V | Programmed | Erased | High |
| 3-4 V | 1.5-2 | V | 0 | V | Erased | Programmed | Low |
| 3-4 V | 1.5-2 | V | 0 | V | Erased | Erased | High |

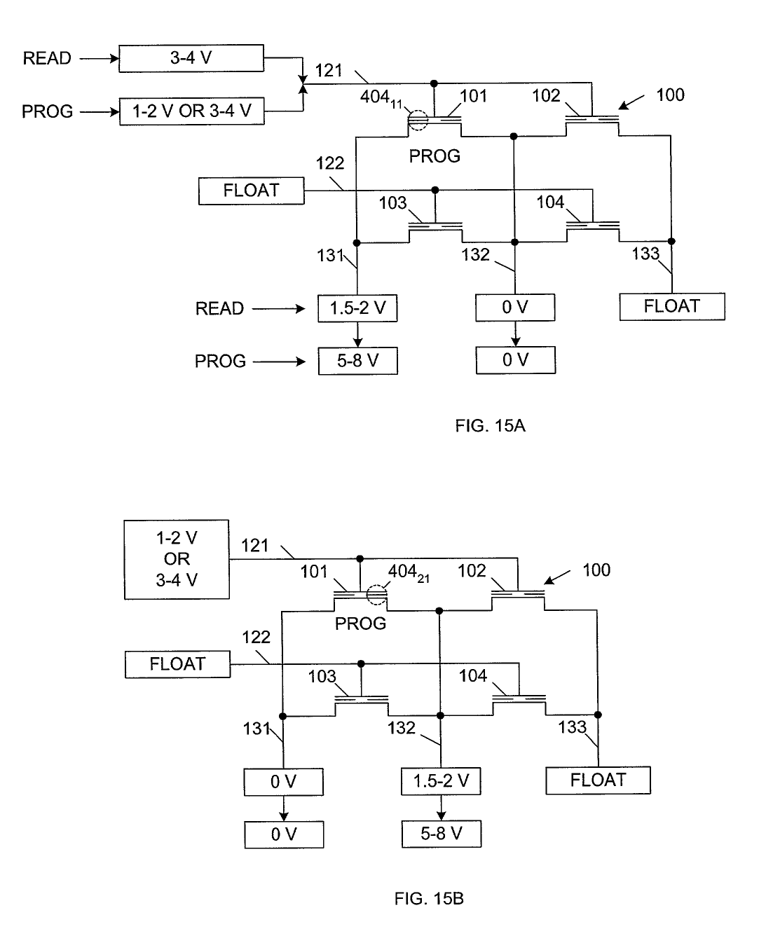

FIGS. 15A and 15B illustrate programming operations of floating gates 404₁₁ and 404₂₁ , respectively, of NVM transistor 101. In general, each programming operation is preceded by a read operation, such that the appropriate programming voltages can be determined. Thus, to program floating gate 404₁₁, a read operation is first performed on floating gate 404₂₁, in the manner illustrated in FIG. 14B. The read state of floating gate 404₂₁ is used to determine the appropriate programming voltages required to program floating gate 404₁₁.

If the read operation determines that floating gate 404₂₁ is in an erased state, then the subsequent programming of floating gate 404₁₁ can be performed as follows. Row decoder 111 is controlled to apply a voltage of about 1-2 Volts to the control gate of NVM transistor 101 via word line 121. Column decoder 112 is controlled to apply a voltage of 0 Volts to bit line 132 and a voltage of about 5 to 8 Volts to bit line 131. Under these conditions, electrons are transferred into floating gate 404₁₁ by hot electron injection.

However, if the read operation of floating gate 404₂₁ determines that floating gate 404₂₁ is in a programmed state, then the subsequent programming of floating gate 404₁₁ is performed as follows. Row decoder 111 is controlled to apply a voltage of about 3-4 Volts to the control gate of NVM transistor 101 via word line 121. Note that the voltage applied to the control gate of NVM transistor 101 must be higher if floating gate 404₂₁ is programmed. Column decoder 112 is controlled to apply a voltage of 0 Volts to bit line 132 and a voltage of about 5 to 8 Volts to bit line 131. Under these conditions, electrons are transferred into floating gate 404₁₁ by hot electron injection.

Advantageously, the read operation and the following program operation require similar voltages. Thus, reading floating gate 404₂₁ and programming floating gate 404₁₁ both require: 0 Volts on bit line 132, a positive voltage on bit line 131, and a positive voltage on word line 121. As a result, the transition between the read operation and the subsequent program operation does not require large signal swings on word line 121 or bit lines 131-132.

Note that row decoder 111 allows word line 122 to float, such that NVM transistors 103 and 104 are not programmed. Also note that column decoder 112 allows bit line 133 to float, such that NVM transistor 102 is not programmed. In addition, over-programming is suppressed in NVM transistor 101 because as the floating gate potential increases, the hot electron channeling is suppressed.

FIG. 15B illustrates the programming of floating gate 404₂₁, which is programmed using the same read-then-program method described above in connection with FIG. 15A.

Other advantages of the 2-bit NVM transistor of the present invention are listed below.

Because floating gates 404₂₁ and 404₁₁ are electrically isolated from each other, the programmed/erased charges are easily maintained in the desired locations. That is, charge migration is not possible. Because there is no charge migration over time, there is no degradation in cycling/endurance.

Moreover, because there is no over-erase or over-programming, the program/erase algorithm may be made relatively simple compared to conventional 2-bit non-volatile memory transistors. That is, a wider program/erase window is allowed because there is no over-program and no over-erase.

Furthermore, the split-gate structure of NVM transistors 101-104 allows the required word line voltages and the required programming current to be relatively low. As a result, these NVM transistors can be scaled relatively easily.

In addition, the polysilicon construction of the floating gates in the present invention enables the NVM transistors to be erased by exposure to ultraviolet light. Thus, after manufacturing, it is possible to use an ultraviolet light to initially reduce the threshold voltages of NVM transistors 101-104. This option is not available in the conventional 2-bit NVM transistor 10 of FIGS. 1 and 2.

Although the invention has been described in connection with several embodiments, it is understood that this invention is not limited to the embodiments disclosed, but is capable of various modifications, which would be apparent to a person skilled in the art. For example, although the invention has been described in connection an n-channel NVM transistor, it is understood that the described conductivity types can be reversed to provide a p-channel NVM transistor. Thus, the invention is limited only by the following claims.

1. A two-bit non-volatile memory transistor comprising:
a semiconductor region having a first conductivity type;
a first source/drain region located in the semiconductor region, the first source/drain region having a second conductivity type, opposite the first conductivity type;
a second source/drain region located in the semiconductor region, the second source/drain region having the second conductivity type, wherein a channel region of the first conductivity type is located between the first and second source/drain regions;
a gate dielectric layer located over the channel region and portions of the first and second source/drain regions;
a first floating gate electrode located on the gate dielectric layer over the channel region and the first source/drain region, wherein the first floating gate electrode stores charge representative of a first data bit;
a second floating gate electrode located on the gate dielectric layer over the channel region and the second source/drain region, wherein the first and second floating gate electrodes are separated by a gap over the channel region, and wherein the second floating gate electrode stores charge representative of a second data bit;
a dielectric layer located over the first floating gate electrode and the second floating gate electrode; and
a control gate located over the dielectric layer.

2. The 2-bit non-volatile memory transistor of claim 1, wherein the first and second floating gate electrodes comprise polysilicon.

3. The 2-bit non-volatile memory transistor of claim 1, further comprising:
a first diffusion bit line continuous with the first source/drain region; and
a second diffusion bit line continuous with the second source/drain region.

4. The 2-bit non-volatile memory transistor of claim 3, further comprising:
a first oxide region located over the first diffusion bit line; and
a second oxide region located over the second diffusion bit line.

5. The 2-bit non-volatile memory transistor of claim 4, wherein a portion of the first floating gate electrode is located over the first oxide region, and a portion of the second floating gate electrode is located over the second oxide region.

6. The 2-bit non-volatile memory transistor of claim 5, further comprising:
a first oxide layer located on an edge of the first floating gate electrode located over the first oxide region; and
a second oxide layer located on an edge of the second floating gate electrode located over the second oxide region.

7. The 2-bit non-volatile memory transistor of claim 1, wherein a first portion of the control gate extends into the gap between the first and second floating gate electrodes.

8. The 2-bit non-volatile memory transistor of claim 7, wherein the first portion of the control gate is separated from the channel region by the dielectric layer and the gate dielectric layer.

9. The 2-bit non-volatile memory transistor of claim 1, wherein the control gate comprises polysilicon and metal silicide.

10. The 2-bit non-volatile memory transistor of claim 1, wherein the gate dielectric layer comprises silicon oxide, and the dielectric layer comprises a first silicon oxide layer, a silicon nitride or silicon oxynitride layer located over the first silicon oxide layer, and a second silicon oxide layer located over the silicon nitride or silicon oxynitride layer.

11. A method of operating a 2-bit non-volatile memory transistor having a control gate, a first floating gate and a second floating gate, the method comprising:
programming the first floating gate by hot electron injection using a first set of programming voltages, wherein the second floating gate is in an erased state when the first floating gate is programmed; and
programming the second floating gate by hot electron injection using a second set of programming voltages, wherein the first floating gate is in a programmed state when the second floating gate is programmed, and wherein the first set of programming voltages includes a first voltage applied to the control gate, and the second set of programming voltages includes a second voltage applied to the control gate, the second voltage being higher than the first voltage.

12. The method of claim 11, wherein the first voltage is about 1-2 Volts, and the second voltage is about 3-4 Volts.

13. The method of claim 11, further comprising:
erasing the first floating gate by applying a first erase voltage to the control gate and a second erase voltage to a first source/drain region of the transistor, thereby removing electrons from the first floating gate; and
erasing the second floating gate by applying the first erase voltage to the control gate and the second erase voltage to a second source/drain region of the transistor, thereby removing electrons from the second floating gate.

14. The method of claim 11, further comprising:
reading the state of the first floating gate by applying a first set of read voltages to the transistor; and
reading the state of the second floating gate by applying a second set of read voltages to the transistor, wherein the first set of read voltages includes a first read voltage applied to a first source/drain region of the transistor and a second read voltage applied to a second source/drain region of the transistor, and wherein the second set of read voltages includes the first read voltage applied to the second source/drain region and the second read voltage applied to the first source/drain region.

15. The method of claim 11, further comprising erasing the first and second floating gates by exposure to ultra-violet light.

16. A method of fabricating a 2-bit non-volatile memory transistor, comprising:
forming a gate dielectric layer over a semiconductor substrate having a first conductivity type;
forming floating gate layer over the gate dielectric layer;
removing a first portion of the floating gate layer, thereby creating an opening through the floating gate layer;
forming a dielectric layer over the floating gate layer, wherein a portion of the dielectric layer extends into the opening and onto the gate dielectric layer;
removing a second portion of the floating gate layer, thereby creating first floating gate and a second floating gate, wherein a first opening is located adjacent to the first floating gate, and a second opening is located adjacent to the second floating gate;
implanting impurities having a second conductivity type, opposite the first conductivity type, into the substrate, through the first and second openings;
thermally growing oxide on the substrate and sidewalls of the first and second gate electrodes through the first and second openings; and
depositing a control gate over the dielectric layer and the oxide.

17. The method of claim 16, wherein the dielectric layer comprises a silicon oxide layer and a silicon nitride or silicon oxynitride layer located over the silicon oxide layer.
